(19) United States
(12) Patent Application Publication
(10) Pub. No.: US 2024/0404824 A1
(43) Pub. Date: Dec. 5, 2024

(54) SEMICONDUCTOR WAFER FOR FORMING SEMICONDUCTOR COMPONENTS

(71) Applicant: AZUR SPACE Solar Power GmbH, Heilbronn (DE)

(72) Inventor: Atsushi NISHIKAWA, Dresden (DE)

(73) Assignee: AZUR SPACE Solar Power GmbH, Heilbronn (DE)

(21) Appl. No.: 18/800,887

(22) Filed: Aug. 12, 2024

Related U.S. Application Data
(63) Continuation of application No. PCT/EP2022/000116, filed on Dec. 23, 2022.

(30) Foreign Application Priority Data
Feb. 10, 2022 (DE) 10 2022 000 520.4

(51) Int. Cl. H01L 21/02

(52) U.S. Cl. CPC H01L 21/02505; H01L 21/02381; H01L 21/0243; H01L 21/02458; H01L 21/02488; H01L 21/02639

(57) ABSTRACT

A semiconductor wafer with a diameter of at least 100 mm for forming semiconductor components, having a substrate with a top and a bottom. The substrate is formed of silicon at the top. Multiple spots having oxygen are formed integrally with the top of the substrate. The spots have oxygen cover at least 0.005% and at most 35% of the top of the substrate. A full-area semiconductor buffer layer sequence integrally covers the top of the substrate and the spots having oxygen. The semiconductor buffer layer sequence has at least one group III nitride layer.

This nonprovisional application is a continuation of International Application No. PCT/EP2022/000116, which was filed on February Dec. 23, 2022, and which claims priority to German Patent Application No. 10 2022 000 520.4, which was filed in Germany on Feb. 10, 2022, and which are both herein incorporated by reference.

### BACKGROUND OF THE INVENTION

### Field of the Invention

The invention relates to a semiconductor wafer for forming semiconductor components.

### Description of the Background Art

Silicon semiconductor wafers with a semiconductor buffer layer sequence resting thereon are known from DE 10 2006 030 305 B3 and DE 102 569 11 A1.

A GaN layer structure is known from US 2012 0 205 616 A1 in which an attempt is made to achieve a reduction in defects in the active GaN layers by means of nanoparticles generated in the gas phase. To this end, a first layer with an amount of nanoparticles is deposited on a substrate during vapor phase epitaxy, wherein the nanoparticles are generated only during the production of the layer and incorporated in the layer. As a result, the lateral overgrowth in the subsequent ELO process is supposed to be improved.

In addition, oxide layers for semiconductor wafers with GaN layers are known from JP 2001 18 54 98 A, from GB 2 434 035 A (which corresponds to US 2008/0087881), from TANAKA SHIGEYASU ET AL: “Structural characterization of GaN laterally overgrown on a (111) Si substrate,” APPLIED PHYSICS LETTERS, AMERICAN INSTITUTE OF PHYSICS, 2 HUNTINGTON QUADRANGLE, MELVILLE, NY 11747, Vol. 79, No. 7, 13 Aug. 2001 (2001-08-13), pages 955-957, XP012030064, ISSN: 0003-6951, from US 2009/272993 A1, from WO 2004/105108 A2, and from TINGKAI LI ET AL: “Chapter 2: Challenge of III-V Materials Integration with Si Microelectronics,” January 2011 (2011-01), III-V COMPOUND SEMICONDUCTORS: INTEGRATION WITH SILICON-BASED MICROELECTRONICS, PAGE(S) 51-96, XP009189029.

### SUMMARY OF THE INVENTION

It is therefore an object of the invention to provided a device that advances the state of the art.

Thus, in a first example, a semiconductor wafer for forming semiconductor components with a diameter of at least 100 mm is provided.

The semiconductor wafer can have a substrate with a top and a bottom, wherein the substrate consists of silicon at the top.

Formed at the top of the substrate are multiple spots having oxygen that are formed integrally with the top.

The spots having oxygen cover at least 0.005% and at most 35% of the top of the substrate.

On the top of the substrate and on the spots having oxygen, a semiconductor buffer layer sequence that integrally covers the top of the substrate or the spots is formed over the full area.

The semiconductor buffer layer sequence can have at least one group III nitride layer.

It should be noted that the terms “III N” or “group Ill nitride” refer to the column of the III-valued elements of the periodic table, such as, in particular, boron, aluminum, gallium, and indium in combination with nitrogen. In particular, the term “III N” also includes layers such as AlGaN or GaN.

It is a matter of course that the layers can each be formed over the full area. In addition, it should be noted that the spots consist mainly of silicon dioxide, which is to say consist of oxide or at least include oxide.

In addition, it should be noted that in the present case the spots on the substrate have a predominantly irregular outer shape, which is to say edge. In some cases, the edge of the spot or the edges of the spots do not always appear to be clearly delimited from the surface of the substrate.

An advantage is that the quality of the semiconductor buffer layer sequence can be improved with the spots. It is surprising that the quality of the semiconductor buffer layer sequence can be improved by means of the spots. In particular, the coalescence during growth of the semiconductor buffer layer sequence can be improved.

The semiconductor buffer layer sequence can have a thickness of at least 1 μm or of at least 4 μm and at most a thickness of 30 μm. In one embodiment, the semiconductor buffer layer sequence has a thickness at the top between 0.5 μm and 10 μm or between 1.0 μm and 5 μm.

The spots having oxygen can cover a minimum of 0.2% to a maximum of 20% or a minimum of 0.01% to a maximum of 30% or a minimum of 0.1% to a maximum of 25% of the top of the substrate and are integrally connected to the top of the substrate.

The spots having oxygen can each have a size of at least 10 nm or of at least 50 nm or at least 100 nm. The spots can have a wide variety of shapes in this case.

The spots having oxygen can each have a size of a maximum of 5 μm or a maximum of 1 μm or a maximum of 0.5 μm.

The spots having oxygen can have a thickness in a range between a monolayer and 4 nm, wherein the thickness of the monolayer is approximately 0.4 nm.

The spots having oxygen can include or consist of a silicon dioxide and/or of a silicon monoxide, referred to in summary hereinbelow as silicon oxide.

The silicon dioxide can be formed as naturally grown oxide. Natural oxide, which is to say silicon dioxide, grows in an environment having oxygen.

It should be noted, however, that the formation of the natural oxide is accelerated in a moist environment. In this case, the density of natural oxide is below the density of a thermally grown oxide. Naturally grown oxide is understood in the present case as a silicon dioxide that preferably is formed at room temperature, but most preferably at a temperature below 100° C. or below 200° C. The thickness of the natural oxide is between a monolayer, which is to say approximately 0.4 nm, and 4 nm. In one improvement, the thickness of the natural oxide is between 1 nm and 2 nm.

A thermally grown oxide can be understood in the present case as a silicon dioxide that preferably is grown at a temperature above 500° C. Preferably, the density of the thermal oxide is more than 30% higher than that of the natural oxide.

The spots having oxygen can include silicon oxide and oxynitride or consist of silicon oxide or consist of oxynitride.

The spots having oxygen can be distributed nearly uniformly on the top. The term “distributed uniformly” is understood in the present case to mean that the spots are located with a uniform distribution over the entire surface of the semiconductor wafer. Wherein in one embodiment, the number of spots on one region of the wafer that includes at least 20% of the total area deviates by no more than 50% from the number of spots in a second region of equal size on the semiconductor wafer.

The semiconductor buffer layer sequence can include a nucleation layer. The term “nucleation layer” is understood in the present case as a layer that improves the growth of another layer arranged directly on the nucleation layer. The nucleation layer is integrally connected to the top of the substrate, except for at the locations where the top has spots according to the invention. At the locations with spots, the nucleation layer is integrally connected to the surface of the spots.

The nucleation layer may not be formed as a continuous layer, but rather as a perforated layer. In this case, the individual islands of the nucleation layer are connected to one another.

The nucleation layer can consist of AlGaN or the nucleation layer can include AlGaN.

The nucleation layer can consist of AlN or the nucleation layer can include AlN.

The nucleation layer can be formed over the full area and has a thickness in a range between 5 nm and 400 nm or has a thickness between 5 nm and 200 nm or has a thickness between 5 nm and 100 nm or has a thickness between 5 nm and 50 nm.

The semiconductor buffer layer sequence can have a masking layer. The nucleation layer can be arranged as the bottommost layer of the semiconductor buffer layer sequence.

The masking layer can include nitride, in particular AlGaN and/or metal nitride.

The masking layer can have a thickness between 10 nm and 500 nm. The masking layer can have a thickness of at most 300 nm or of at most 200 nm or of at most 100 nm.

The semiconductor buffer layer sequence can have GaN/AlGaN layers arranged in alternation.

The substrate can have a thickness greater than 200 μm or greater than 1.2 mm or greater than 1.6 mm and less than 3 mm.

The substrate can be formed of silicon. The substrate can have a <100> or a <111> crystal orientation. In one improvement, the substrate can have n-doping or p-doping or the substrate is undoped.

The substrate can be produced in accordance with the float zone process or in accordance with the Czochralski process or in accordance with another process.

Also, a substrate with spots is provided in a first step in accordance with the present method for producing a semiconductor wafer. In a following step, a nucleation layer is arranged on the spotted surface of the substrate.

It is a matter of course that, in the first step, the spotted substrate wafer can be placed in an MOVPE system in order to apply additional layers to the substrate, which is to say to carry out epitaxy on the substrate.

A masking layer can be arranged on the nucleation layer in another step.

A semiconductor buffer layer sequence can be either applied on the masking layer and/or a semiconductor buffer layer sequence is applied on the nucleation layer, which is to say with no masking layer.

In other words, a semiconductor buffer layer sequence including at least the nucleation layer can be formed in one step.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a cross-sectional view of a semiconductor wafer with a semiconductor buffer layer sequence;

FIG. 2 shows a top view of the semiconductor wafer, shown in connection with the illustration in FIG. 1; and

FIG. 3 shows a cross-sectional view of the semiconductor wafer with the Ill N layers formed in the semiconductor buffer layer sequence.

### DETAILED DESCRIPTION

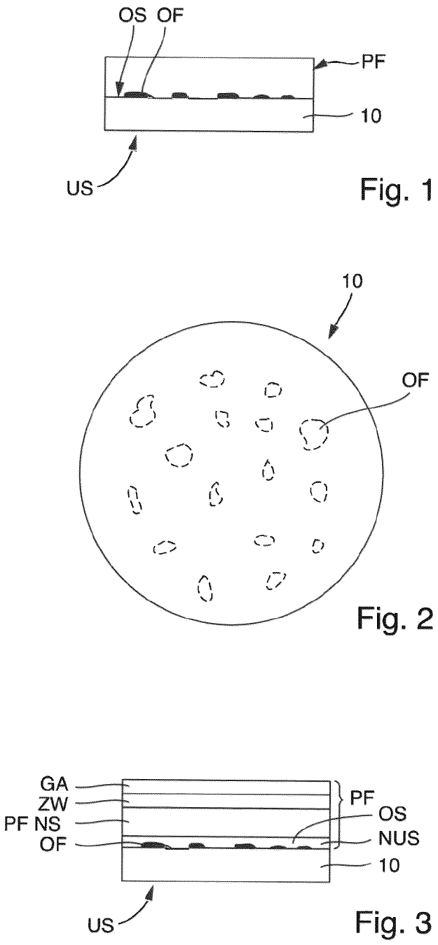

The illustration in FIG. 1 shows a cross-sectional view of a semiconductor wafer formed of a substrate 10 with a top OS and a bottom US. The substrate 10 consists of monocrystalline silicon, at least at the top, and has a diameter of at least 100 mm.

At the top OS of the substrate 10 are spots OF having oxygen that are integrally connected to the substrate 10. The spots can have a varying thickness along the applicable longitudinal extent.

Formed on the top OS of the substrate 10 and on the spots OF having oxygen is a full-area semiconductor buffer layer sequence PF.

The semiconductor buffer layer sequence PF includes at least one group Ill nitride layer.

Shown in the illustration in FIG. 2 is a top view of the semiconductor wafer, which is shown in connection with the illustration in FIG. 1. Only the differences from the illustration in FIG. 1 are explained below. The spots OF having oxygen are distributed nearly uniformly on the top. The spots OF have irregular outlines and cover at least 0.005% of the top OS of the substrate 10.

In the illustration in FIG. 3, a cross-sectional view of the semiconductor wafer is shown. Only the differences from the illustration in FIG. 1 are explained below.

The semiconductor buffer layer sequence PF includes a nucleation layer NUS, which is formed as a full-area layer on the top OS of the substrate 10 that includes the spots. The nucleation layer NUS is formed integrally on the top OS. Arranged on the nucleation layer NUS is a layer PFNS composed of a III N material. Formed on the layer PFNS is an intermediate layer ZW. Formed on the intermediate layer ZW is a full-area layer GA composed of GaN.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A semiconductor wafer for forming semiconductor components with a diameter of at least 100 mm, the semiconductor wafer comprising:
a substrate with a top and a bottom, wherein the substrate is formed of silicon at the top;
at least two spots having oxygen that are formed integrally with the top of the substrate, the spots having oxygen cover at least 0.005% and at most 35% of the top of the substrate, and the spots having oxygen are formed exclusively on the top as part of the substrate;
a full-area semiconductor buffer layer sequence integrally covering the top of the substrate and the spots having oxygen, the semiconductor buffer layer sequence having at least one group III nitride layer,
wherein the semiconductor buffer layer sequence includes a nucleation layer,
wherein the nucleation layer is integrally connected to the top of the substrate except for at the locations where the top has spots, and,
wherein, at the locations with spots, the nucleation layer is integrally connected to the surface of the spots.

2. The semiconductor wafer according to claim 1, wherein the spots having oxygen cover a minimum of 0.2% to a maximum of 20% or a minimum of 0.01% to a maximum of 30% or a minimum of 0.1% to a maximum of 25% of the top of the substrate, and wherein the spots having oxygen each have a size of at least 10 nm or of at least 50 nm or at least 100 nm.

3. The semiconductor wafer according to claim 1, wherein the spots having oxygen include silicon dioxide and/or oxynitride, or the spots having oxygen consist of silicon dioxide or of oxynitride.

4. The semiconductor wafer according to claim 1, wherein the number of the spots having oxygen on one region of the wafer that includes at least 20% of the total area deviates by no more than 50% from the number of spots in a second region of equal size on the semiconductor wafer.

5. The semiconductor wafer according to claim 1, wherein the silicon dioxide is formed as naturally grown oxide and has a thickness between 0.4 nm and 4 nm.

6. The semiconductor wafer according to claim 1, wherein the nucleation layer includes AlGaN or consists of AlGaN.

7. The semiconductor wafer according to claim 1, wherein the nucleation layer includes AlN or consists of AlN.

8. The semiconductor wafer according to claim 1, wherein the nucleation layer is formed over the full area and has a thickness in a range between 5 nm and 400 nm or has a thickness between 5 nm and 200 nm or has a thickness between 5 nm and 100 nm or has a thickness between 5 nm and 50 nm.

9. The semiconductor wafer according to claim 1, wherein the semiconductor buffer layer sequence has a masking layer arranged on the nucleation layer.

10. The semiconductor wafer according to claim 9, wherein the masking layer includes nitride, in particular AlGaN and/or metal nitride.

11. The semiconductor wafer according to claim 9, wherein the masking layer has a thickness between 10 nm and 500 nm.

12. The semiconductor wafer according to claim 1, wherein the semiconductor buffer layer sequence has GaN/AlGaN layers arranged in alternation.

13. A method for producing a semiconductor wafer according to claim 1, the method comprising:
providing a substrate with spots; and
forming a semiconductor buffer layer sequence on the substrate.

14. The method for producing a semiconductor wafer according to claim 13, wherein a nucleation layer is arranged on the substrate as part of the semiconductor buffer layer sequence.

15. The method for producing a semiconductor wafer according to claim 13, wherein a masking layer is arranged on the nucleation layer.
